(19) United States
(12) Patent Application Publication
(10) Pub. No.: US 2012/0077314 A1
(43) Pub. Date: Mar. 29, 2012

(54) METHOD OF FABRICATING SEMICONDUCTOR STACK PACKAGE

(75) Inventors: Sang-sick PARK, Seoul (KR); Dong-hyeon JANG, Yongin-si (KR); Chang-seong JEON, Hwaseong-si (KR); Teak-boon LEE, Hwaseong-si (KR)

(73) Assignee: Samsung Electronics Co., Ltd., Suwon-si (KR)

(21) Appl. No.: 13/241,945

(22) Filed: Sep. 23, 2011

(30) Foreign Application Priority Data
Sep. 28, 2010 (KR) 10-2010-0093804

(51) Int. Cl. H01L 21/98

(52) U.S. Cl. 438/109; 257/E21.705

(57) ABSTRACT

Methods of fabricating a semiconductor stack package having a high capacity, a small volume and reliability. According to the method of fabricating a semiconductor stack package, a first semiconductor substrate including a plurality of first semiconductor chips is attached to a chip protection film. The chip protection film is expanded such that the plurality of the first semiconductor chips are spaced apart from each other. A plurality of second semiconductor chips are attached to the plurality of the first semiconductor chips, respectively. A molding layer is formed between the plurality of the first semiconductor chips and between the plurality of the second semiconductor chips. The molding layer and the chip protection film are sawed to separate the semiconductor stack package comprising the first semiconductor chip and the second semiconductor chip into a unit.

### CROSS-REFERENCE TO RELATED APPLICATIONS

This application claims the benefit of Korean Patent Application No. 10-2010-0093804, filed on Sep. 28, 2010, in the Korean Intellectual Property Office, the disclosure of which is incorporated herein in its entirety by reference.

### BACKGROUND OF THE INVENTION

1. Field of the Invention

The inventive concept relates to methods of fabricating a semiconductor stack package, and more particularly, to methods of fabricating a semiconductor package in which a plurality of semiconductor chips are stacked by using a through silicon via (TSV).

2. Description of the Related Art

Recently, as electronic devices become more integrated and smaller, semiconductor packages have been increasing in integration densities and performance and are smaller in size. In particular, a system in package including a logic chip and a memory chip as one package has been developed. There is still a need to develop a die stack package in which memory chips are stacked without a printed circuit board (PCB) to be mounted in a system in package.

### SUMMARY OF THE INVENTION

When dies having the same size are stacked on a semiconductor substrate, it is difficult to secure an underfill space due to a narrow scribe line. In addition, as a semiconductor substrate is cut into individual semiconductor chips, sides of the individual semiconductor chips are exposed.

Thus, the inventive concept provides methods of fabricating a semiconductor stack package having a high capacity, a small volume and high reliability.

Additional features and utilities of the present general inventive concept will be set forth in part in the description which follows and, in part, will be obvious from the description, or may be learned by practice of the general inventive concept.

Exemplary embodiments of the present general inventive concept provide a semiconductor stack package including a second semiconductor chip, a first semiconductor chip, a chip protection film, and a molding layer. The second semiconductor chip includes a through electrode. The first semiconductor chip is stacked on the second semiconductor chip. The chip protection film covers the upper surface of the first semiconductor chip. The molding layer covers the sides of the first semiconductor chip and the sides of the second semiconductor chip.

The molding layer may be underfilled between the first semiconductor chip and the second semiconductor chip.

The area of the first semiconductor chip may be greater than that of the second semiconductor chip that is positioned lower than the first semiconductor chip.

Exemplary embodiments of the present general inventive concept also provide a method of fabricating a semiconductor stack package. A first semiconductor substrate including a plurality of first semiconductor chips is attached to a chip protection film. The chip protection film is expanded such that the plurality of the first semiconductor chips are spaced apart from each other. The plurality of second semiconductor chips, each of which includes a through electrode, are attached to the plurality of the first semiconductor chips such that each of the second semiconductor chips corresponds to each of the first semiconductor chips. A molding layer is formed between the plurality of the first semiconductor chips and between the plurality of the second semiconductor chips. The molding layer and the chip protection film are sawed to separate the semiconductor stack package including the first semiconductor chip and the second semiconductor chip stacked on the first semiconductor chip into a unit.

In the attaching the first semiconductor substrate to the chip protection film, the chip protection film may include an adhesive layer having a B-stage phase and a protection layer having a C-stage phase. In this regard, the first semiconductor substrate may be attached to the adhesive layer of the chip protection film.

The first semiconductor substrate may have a first surface in which an active region is formed and a second surface that is opposite to the first surface. In this regard, the second surface of the first semiconductor substrate may be attached to the chip protection film.

In addition, each of the plurality of first semiconductor chips may include a first connection bump disposed on the first surface. Each of the plurality of second semiconductor chips may include a second connection bump electrically connected to the through electrode. In this regard, the plurality of the second semiconductor chips may be attached to the plurality of the first semiconductor chips such that the through electrode is electrically connected to the first connection bump of the plurality of the first semiconductor chips.

The first semiconductor substrate may be sawed along a scribe line to separate the plurality of the first semiconductor chips from each other.

A modified region may be formed in the first semiconductor substrate along the scribe line using a laser beam. In this regard, the plurality of the first semiconductor chips are separated from each other along the modified region in the expanding the chip protection film.

The forming the molding layer may include injecting a molding material between the plurality of the first semiconductor chips and between the plurality of second semiconductor chips on the chip protection film, and curing the molding material In this regard, the chip protection film may also be cured in the curing the molding material. In addition, the molding material may also be injected between the plurality of the first semiconductor chips and the plurality of the second semiconductor chips which correspond to each other.

The sides of the first semiconductor chip and the second semiconductor chip of the semiconductor stack package may be covered with and protected by the molding layer. In addition, the semiconductor stack package may be protected by the molding layer and the chip protection film.

The method may further include attaching a plurality of third semiconductor chips, each of which includes a through electrode, to the plurality of the second semiconductor chips such that each of the third semiconductor chips corresponds to each of the second semiconductor chips. The molding layer may be formed between the plurality of the third semiconductor chips in the forming the molding layer.

The attaching the plurality of the second semiconductor chips to the first semiconductor substrate may include: attaching a plurality of third semiconductor chips, each of which includes a through electrode, to the plurality of the second semiconductor chips such that each of the third semiconductor chips corresponds to each of the second semiconductor chips; and attaching the plurality of the second semiconductor chips on which the plurality of the third semiconductor chips are stacked to the first semiconductor substrate.

The attaching the plurality of the second semiconductor chips to the first semiconductor substrate may include: interposing an underfill film between the plurality of the second semiconductor chips and the plurality of the first semiconductor chips which correspond to each other, and attaching the plurality of the second semiconductor chips to the plurality of the first semiconductor chips by performing a thermo-compression.

The area of the second semiconductor chip may be less than that of the first semiconductor chip.

The plurality of the second semiconductor chips may have a first surface that faces the first semiconductor substrate and a second surface that is opposite to the first surface. Each of the plurality of the second semiconductor chips may further include a second connection bump formed on the second surface and electrically connected to the through electrode. The molding layer may cover the second surface of the plurality of the second semiconductor chips to expose the second connection bump.

The plurality of the second semiconductor chips may be respectively attached to the plurality of the first semiconductor chips such that a surface on which the active region is formed to face the first semiconductor substrate.

Exemplary embodiments of the present general inventive concept also provide a method of fabricating a semiconductor stack package. A first semiconductor substrate including a plurality of first semiconductor chips is attached to a chip protection film. The chip protection film is expanded such that the plurality of the first semiconductor chips are spaced apart from each other. A plurality of second semiconductor chips are attached to the plurality of the first semiconductor chips such that each of the second semiconductor chips corresponds to each of the first semiconductor chips. A molding layer is formed between the plurality of the first semiconductor chips and between the plurality of the second semiconductor chips. The molding layer and the chip protection film are sawed between the plurality of the first semiconductor chips.

Each of the plurality of the second semiconductor chips may include a through electrode. In this regard, the plurality of the first semiconductor chips may be electrically connected to an external device via the through electrode of the plurality of the second semiconductor chips respectively corresponding to the first semiconductor chips.

Exemplary embodiments of the present general inventive concept also provide a method of fabricating a semiconductor stack package. A first semiconductor substrate including a plurality of first semiconductor chips and a second semiconductor substrate including a plurality of second semiconductor chips are prepared. The first semiconductor substrate is attached to a chip protection film. The second semiconductor substrate is attached to the first semiconductor substrate such that the plurality of the second semiconductor chips respectively correspond to the plurality of the first semiconductor chips. The second semiconductor substrate and the first semiconductor substrate are sawed. The chip protection film is expanded such that the plurality of the first semiconductor chips are spaced apart from each other and the plurality of the second semiconductor chips are spaced apart from each other. A molding layer is formed between the plurality of the first semiconductor chips and between the plurality of the second semiconductor chips. The molding layer and the chip protection film are sawed between the plurality of the second semiconductor chips.

Exemplary embodiments of the present general inventive concept also provide a method of fabricating a semiconductor stack package, the method including preparing a first semiconductor substrate comprising a plurality of first semiconductor chips to a chip protective film; expanding the chip protection film such that the plurality of the first semiconductor chips are spaced apart from each other; sequentially attaching second and third semiconductor chips onto the spaced apart first semiconductor chips using first and second underfill films, respectively, such that the first underfill film is interposed between a first surface of the first semiconductor chip and a second surface of the second semiconductor chip and the second underfill film is interposed between the first surface of the second semiconductor chip and a second surface of the third semiconductor chip; forming a molding layer between the first semiconductor chips, between the second semiconductor chips and the third semiconductor chips; and cutting the molding layer and the chip protection film to separate into semiconductor stack packages.

In an embodiment, the first semiconductor chips are attached to the second semiconductor chips using through electrodes and the third semiconductor chips are connected to the second semiconductor chips using through electrodes such that first, second and third semiconductor chips correspond to each other.

In an embodiment, each of the plurality of first semiconductor chips comprises first connection bumps disposed on the first surface thereof, each of the plurality of second semiconductor chips comprises second connection bumps electrically connected to the through electrodes thereof, and the plurality of the second semiconductor chips are attached to the plurality of the first semiconductor chips such that the through electrodes are electrically connected to the first connection bumps of the plurality of the first semiconductor chips.

In an embodiment, each of the third semiconductor chips comprises third connection bumps electrically connected to the through electrodes thereof, and the plurality of third semiconductor chips are attached to the plurality of the second semiconductor chips such that the through electrodes are electrically connected to the second connection bumps of the plurality of the second semiconductor chips.

### BRIEF DESCRIPTION OF THE DRAWINGS

These and/or other features and utilities of the present general inventive concept will become apparent and more readily appreciated from the following description of the embodiments, taken in conjunction with the accompanying drawings of which:

FIG. 1 is a cross-sectional view of a semiconductor stack package according to an embodiment of the inventive concept;

FIG. 2 is a cross-sectional view of a semiconductor stack package according to another embodiment of the inventive concept;

FIG. 3 is a cross-sectional view of a semiconductor stack package according to another embodiment of the inventive concept;

FIG. 4 is a cross-sectional view of a semiconductor stack package according to still another embodiment of the inventive concept;

FIG. 5 is a cross-sectional view of a semiconductor stack package according to yet another embodiment of the inventive concept;

FIG. 6 is a cross-sectional view of a semiconductor stack package according to yet another embodiment of the inventive concept;

FIGS. 7 to 14 are diagrams describing a method of fabricating a semiconductor stack package according to the embodiment of FIG. 1 according to a fabricating order;

FIGS. 15 and 16 are diagrams describing a method of fabricating a semiconductor stack package according to the embodiment of FIG. 2;

FIGS. 17 and 18 are diagrams describing a method of fabricating a semiconductor stack package according to the embodiment of FIG. 3;

FIGS. 19 and 20 are diagrams describing a method of fabricating a semiconductor stack package according to the embodiment of FIG. 4;

FIG. 21 is a diagram describing a method of fabricating a semiconductor stack package according to the embodiment of FIG. 5;

FIG. 22 is a diagram describing a method of fabricating a semiconductor stack package according to the embodiment of FIG. 6;

FIGS. 23 and 24 are diagrams describing a method of fabricating a semiconductor stack package according to a modified embodiment of FIG. 1 according to a fabricating order;

FIG. 25 is a schematic block diagram illustrating a memory card according to an embodiment of the inventive concept; and

FIG. 26 is a schematic block diagram illustrating an electronic system according to an embodiment of the inventive concept.

### DETAILED DESCRIPTION OF THE PREFERRED EMBODIMENTS

Hereinafter, the inventive concept will now be described more fully with reference to the accompanying drawing, in which exemplary embodiments of the inventive concept is shown. As the inventive concept allows for various changes and numerous embodiments, particular embodiments will be illustrated in the drawings and described in detail in the written description.

These embodiments are provided so that this disclosure will be thorough and complete, and will fully convey the scope of the invention to those skilled in the art. The inventive concept may, however, be embodied in many different forms and should not be construed as limited to the exemplary embodiments set forth herein.

The terms used herein are used to describe embodiments of the inventive concept, and not to limit the inventive concept. An expression used in the singular encompasses the expression of the plural, unless it has a clearly different meaning in the context. In the present specification, it is to be understood that the terms such as “including”, “comprising”, or “having,” etc., are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added. As used herein, the term “and/or” includes any one or at least one of combinations of one or more of the associated listed items.

While such terms as “first,” “second,” etc., may be used to describe various components, such components must not be limited to the above terms. The above terms are used only to distinguish one component from another.

Unless otherwise defined, all terms including technical and scientific terms used herein have the same meaning as commonly understood by one of ordinary skill in the art to which this inventive concept belongs. It will be further understood that terms will not be interpreted in an idealized or overly formal sense unless expressly so defined herein.

Like reference numerals refer to like elements throughout. It will be understood that when an element or a layer is referred to as being “on” another element or layer, the element or layer can be directly on another element or layer or intervening elements or layers. In the accompanying drawings, thicknesses and sizes of layers and regions are exaggerated for clarity. In the drawings, the illustrated features may be changed due to, for example, the manufacturing technology and/or tolerance. Accordingly, it should be understood that the example embodiments of the inventive concept are not limited to the drawings but include modifications of the features of elements caused due to, for example, the manufacture.

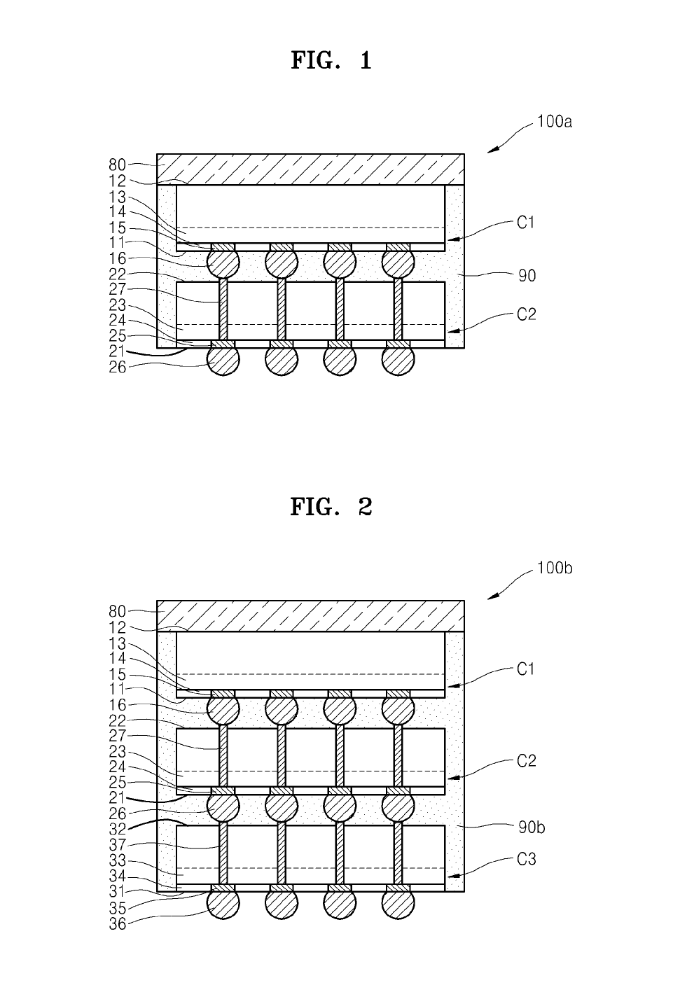

FIGS. 1 to 6 are cross-sectional views of semiconductor stack packages according to embodiments of the inventive concept.

FIG. 1 is a cross-sectional view of a semiconductor stack package 100a according to an embodiment of the inventive concept.

Referring to FIG. 1, the semiconductor stack package 100a includes a plurality of semiconductor chips C1 and C2. Although the semiconductor stack package 100a includes two semiconductor chips C1 and C2 in FIG. 1, it may also include 3 or more semiconductor chips. The number of the semiconductor chips is not limited thereto.

A semiconductor chip C1 disposed in an upper layer refers to a first semiconductor chip and a semiconductor chip C2 disposed in a lower layer refers to a second semiconductor chip according to a fabricating order. This will be described later.

The second semiconductor chip C2 may be formed by forming an individual semiconductor device including a transistor, a resistor, a capacitor, a conductive wiring, or the like on a semiconductor substrate, and performing separating the chip. The semiconductor substrate may be any semiconductor substrate having a flat upper surface, for example, a silicon substrate. Alternatively, the semiconductor substrate may be a compound semiconductor substrate such as a silicon on insulator (SOI) substrate, a silicon-germanium substrate, a silicon-carbide substrate, or a gallium-arsenic substrate. Hereinafter, the term “semiconductor chip” indicates an individual semiconductor chip formed by processing a semiconductor wafer and dividing the semiconductor wafer into a plurality of semiconductor chips.

The second semiconductor chip C2 may have a first surface 21 and a second surface 22 that is opposite to the first surface 21. The first surface 21 has a second active region 23 in which an individual semiconductor device is formed and may refer to an active surface.

A second protection layer 24 and a conductive second pad 25 may be formed on the first surface 21 of the second semiconductor chip C2. In addition, a second connection bump 26 is attached to the second pad 25 to be electrically connected to an external device such as another semiconductor chip or board. The second connection bump 26 may partially be electrically connected to an individual semiconductor device formed in the second active region 23 by redistribution (not shown).

The second connection bump 26 may include one selected from the group consisting of a conductive bump, a conductive spacer, a solder ball, a pin grid array (PGA) and any combination thereof.

The second protection layer 24 may include a silicon nitride. A distribution or redistribution for electrically connecting the second pad 25 with the individual semiconductor device contained in the second semiconductor chip C2 may be formed under or in the second protection layer 24.

The second pad 25 may be exposed by the second protection layer 24. As shown in FIG. 1, an exposed surface of the second pad 25 and an exposed surface of the second protection layer 24 may be disposed in the same plane. Alternatively, the exposed surface of the second pad 25 may be disposed in a higher or lower plane than the exposed surface of the second protection layer 24.

A portion of the second connection bump 26 may be electrically connected to a second through electrode 27 to be electrically connected to the first semiconductor chip C1. In this regard, the term ‘electrically connected to the semiconductor chip’ indicates being electrically connected to the individual semiconductor device formed in the semiconductor chip.

The second through electrode 27 may be formed to pass through the second semiconductor chip C2. Optionally, however, the second through electrode 27 may not be exposed to the first surface 21 or the second surface 22 by a conductive material such as the second pad 25. The second through electrode 27 may partially protrude from the second surface 22 of the second semiconductor chip C2. The second through electrode 27 may include Ag, Au, Cu, W, Al or In.

An insulating material layer (not shown) may be formed around the second through electrode 27 so that portions of the second semiconductor chip C2 which contact the second through electrode 27 may be electrically insulated from the second through electrode 27. The insulating material layer may include a silicon oxide, a silicon nitride, a silicon oxynitride, a metal silicate, or an organic silicate.

In addition, a barrier layer (not shown) and/or a seed layer (not shown) may further be formed between the second through electrode 27 and the insulating material layer. The barrier layer may include Ti, TiN, Ru, Co, Mn, WN, Ni, NiB, Ta or TaN.

In general, the second through electrode 27 may refer to a through silicon via (TSV). The term ‘through silicon via’ is used since semiconductor chips are generally formed of silicon, and thus does not always indicate passing through the silicon substrate. Thus, if a through electrode passes through a semiconductor chip formed of any material other than silicon, the through electrode may refer to a TSV.

The first semiconductor chip C1 includes a first surface 11 on which a first active region 13 is disposed and a second surface 12 that is opposite to the first surface 11. A first protection layer 14, a first pad 15 that is conductive and exposed by the first protection layer 14, and a first connection bump 16 attached to the first pad 15 to be electrically connected to the first pad 15 are formed on the first surface 11.

The first semiconductor chip C1 may be disposed on the second surface 22 of the second semiconductor chip C2 such that the first surface 11 faces the second semiconductor chip C2. In this regard, the first connection bump 16 formed on the first surface 11 of the first semiconductor chip C1 may contact the second through electrode 27 of the second semiconductor chip C2, so that the second through electrode 27 may be electrically connected to the first semiconductor chip C1.

Characteristics of the first active region 13, the first connection bump 16, the first protection layer 14, and the first pad 15 of the first semiconductor chip C1 which are not described herein may be the same as those of the second active region 23, the second connection bump 26, the second protection layer 24, and the second pad 25 of the second semiconductor chip C2.

Although the first semiconductor chip C1 does not illustrate a through electrode in FIG. 1, the first semiconductor chip C1 may include a through electrode. In this regard, the first semiconductor chip C1 may be the same type as the second semiconductor chip C2 manufactured by the same process.

The first and second pads 15 and 25, the first and second connection bumps 16 and 26, and the second through electrode 27 are illustrated as being linearly aligned herein, but the alignment thereof is not limited thereto. The alignment of the first and second pads 15 and 25, the first and second connection bumps 16 and 26, and the second through electrode 27 is not limited as long as they are connected to each other as described above. In other words, the first and second pads 15 and 25, the first and second connection bumps 16 and 26, and the second through electrode 27 may not be linearly aligned by the redistribution of the first and second semiconductor chips C1 and C2 while still being connected to each other.

In addition, the second connection bump 26, the second pad 25, the second through electrode 27, the first connection bump 16, and the first pad 15 are sequentially connected herein, but the inventive concept is not limited thereto. In other words, a portion of the second connection bump 26 and the second pad 25 may be connected to the second through electrode 27, and another portion thereof may be connected to the second active region 23.

A portion of the second connection bump 26 may also be connected to both of the first and second active regions 13 and 23. For example, if a portion of the second connection bump 26 is partially connected to an external power source, the portion of the second connection bump 26 may be connected to both of the first and second active regions 13 and 23 to supply power to the first and second active regions 13 and 23. That is, the relationship among the first and second pads 15 and 25, the first and second connection bumps 16 and 26, and the second through electrode 27 described above is exemplary only, and is not limited thereto.

The first semiconductor chip C1 and the second semiconductor chip C2 may have the same area. However, the area of the first semiconductor chip C1 disposed at the upper layer may be greater than that of the second semiconductor chip C2. This will be described later. On the other hand, the area of the first semiconductor chip C1 may be less than that of the second semiconductor chip C2.

The first and second semiconductor chips C1 and C2 may be the same type semiconductor chip with the same area. Alternatively, the first and second semiconductor chips C1 and C2 may be different types of semiconductor chips with different areas.

One of the first and second semiconductor chips C1 and C2 may be a semiconductor chip including a memory device. In addition, the other of the first and second semiconductor chips C1 and C2 may be a semiconductor chip including a logic device. For example, the semiconductor stack package 100a may include semiconductor chips including a memory device and semiconductor chips controlling the memory device. The semiconductor stack package 100a may be a system on chip (SoC) including various types of semiconductor chips.

The second surface 12 of the first semiconductor chip C1 may be covered with a chip protection film 80. The chip protection film 80 may be formed of a material that expands under predetermined conditions, for example, by a force in a predetermined temperature range. The chip protection film 80 may include a plurality of layers. This will be described later with reference to FIG. 8.

The chip protection film 80 may be a non-conducting film (NCF). The chip protection film 80 may include an epoxy, a silicon, a polyimide, or an acrylic material. In addition, the chip protection film 80 may be formed of a material including a phenol type, an acid anhydride type, or an amine type curing agent. The chip protection film 80 may be formed of a heat sensitive material, a thermoplastic material, or an UV curable material having an acrylic polymer.

The first and second semiconductor chips C1 and C2 may be molded by a molding layer 90. The molding layer 90 may completely cover sides of the first and second semiconductor chips C1 and C2. In addition, the molding layer 90 may be disposed between the first semiconductor chip C1 and the second semiconductor chip C2. The first surface 21 of the second semiconductor chip C2 may not be covered by the molding layer 90, but instead may be exposed. However, the first surface 21 of the second semiconductor chip C2 may be covered with the molding layer 90. This will be described later. In addition, as shown FIG. 1, the upper surface of the molding layer 90 may be partially covered with the chip protection film 80.

The molding layer 90 may include an epoxy, a silicon, a polyimide, or an acrylic material or ceramic. The molding layer 90 may be formed of a material including a phenol type, an acid anhydride type, or an amine type curing agent and/or UV curable material. The molding layer 90 may include a material having similar properties to the chip protection film 80. For example, the main components of the molding layer 90 and the chip protection film 80 may be the same or partially the same. In addition, curing conditions for the molding layer 90 may be similar to those for the chip protection film 80.

The semiconductor stack package 100a may be protected by only exposing the first surface 21 and the second connection bump 26 attached to the first surface 21, and covering the other portions of the semiconductor stack package 100a with the chip protection film 80 and the molding layer 90.

Semiconductor stack packages that will be described later according to another embodiment of the inventive concept may also include the same or corresponding components of the semiconductor stack package 100a shown in FIG. 1.

FIG. 2 is a cross-sectional view of a semiconductor stack package 100b according to another embodiment of the inventive concept.

Referring to FIG. 2, the semiconductor stack package 100b is substantially the same as the semiconductor stack package 100a of FIG. 1, except that the semiconductor stack package 100b includes a third semiconductor chip C3.

The semiconductor stack package 100b includes first to third semiconductor chips C1, C2, and C3. The first and second semiconductor chips C1 and C2 are described above with reference to FIG. 1, and thus the descriptions thereof will not be repeated. In addition, components shown in FIG. 2 which are not described may correspond to those shown in FIG. 1, and thus the descriptions thereof will not be repeated.

The third semiconductor chip C3 includes a first surface 31 on which a third active region 33 is disposed and a second surface 32 that is opposite to the first surface 31. A third protection layer 34, a third pad 35 that is conductive and exposed by the third protection layer 34, and a third connection bump 36 electrically connected to the third pad 35 are formed on the first surface 31. In addition, third semiconductor chip C3 may include a third through electrode 37 passing through the third semiconductor chip C3. The third through electrode 37 is electrically connected to the third connection bump 36 via the third pad 35.

The third semiconductor chip C3 may be disposed under the first surface 21 of the second semiconductor chip C2 such that the second surface 32 faces the second semiconductor chip C2. In this regard, the third through electrode 37 of the third semiconductor chip C3 exposed on the second surface 32 contacts the second connection bump 26 of the second semiconductor chip C2, so that the third through electrode 37 may be electrically connected to the second semiconductor chip C2.

Characteristics of the third active region 33, the third connection bump 36, the third protection layer 34, the third through electrode 37, and the third pad 35 of the third semiconductor chip C3 which are not described herein may be the same as those of the second active region 23, the second connection bump 26, the second protection layer 24, the second through electrode 27, and the second pad 25 of the second semiconductor chip C2.

In FIG. 2, the first to third semiconductor chips C1, C2, and C3 have the same area, but the inventive concept is not limited thereto. In addition, the first to third semiconductor chips C1, C2, and C3 may be the same type of semiconductor chip or different types of semiconductor chips.

In FIG. 2, the second through electrode 27 and the third through electrode 37 are linearly aligned, but the inventive concept is not limited thereto. The second and third through electrodes 27 and 37 may not be linearly aligned by redistribution of the second and third semiconductor chips C2 and C3.

A molding layer 90b may cover not only the first and second semiconductor chips C1 and C2 but also the third semiconductor chip C3. As shown in FIG. 2, the sides of the third semiconductor chip C3 may be covered by the molding layer 90b, and the molding layer 90b may also be disposed between the third semiconductor chip C3 and the second semiconductor chip C2. The molding layer 90b may correspond to the molding layer 90 shown in FIG. 1.

Although the semiconductor stack package 100b includes three semiconductor chips C1, C2, and C3 in FIG. 2, the number of the semiconductor chips is not limited thereto. The semiconductor stack package 100b may include 4 or more semiconductor chips.

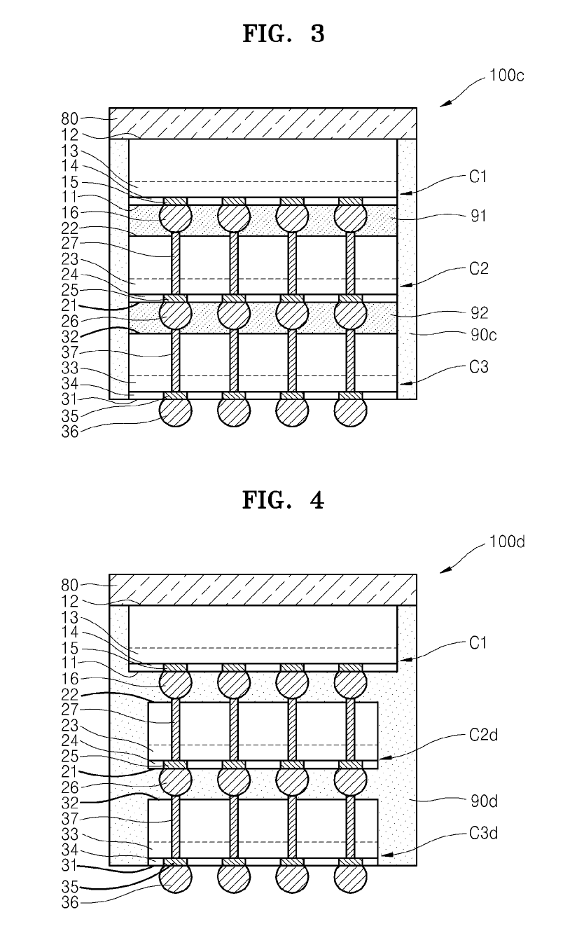

FIG. 3 is a cross-sectional view of a semiconductor stack package 100c according to another embodiment of the inventive concept.

Referring to FIG. 3, the semiconductor stack package 100c is substantially the same as the semiconductor stack package 100b of FIG. 2, except that the semiconductor stack package 100c includes underfill films 91 and 92.

The semiconductor stack package 100c includes first to third semiconductor chips C1, C2, and C3. The first to third semiconductor chips C1, C2, and C3 are described above with reference to FIGS. 1 and 2, and thus the descriptions thereof will not repeated. In addition, components shown in FIG. 3 which are not described may correspond to those shown in FIG. 1, and thus the descriptions thereof will not be repeated.

The first underfill film 91 may be interposed between the first surface 11 of the first semiconductor chip C1 and the second surface 22 of the second semiconductor chip C2. The first underfill film 91 may serve as an adhesive layer between the first semiconductor chip C1 and the second semiconductor chip C2. In addition, the first underfill film 91 may fill space between the first semiconductor chip C1 and the second semiconductor chip C2.

The first underfill film 91 may be a non-conducting film (NCF). The first underfill film 91 may include an epoxy, a silicon, a polyimide, or an acrylic material. In addition, the first underfill film 91 may be formed of a material including a phenol type, an acid anhydride type, or an amine type curing agent. The first underfill film 91 may be formed of a heat sensitive material, a thermoplastic material, or an UV curable material having an acrylic polymer.

The first underfill film 91 may include a material having similar properties to the chip protection film 80. For example, the main components of the first underfill film 91 and the chip protection film 80 may be the same or partially the same. In addition, curing conditions for the first underfill film 91 may be similar to those for the chip protection film 80.

The second underfill film 92 may be disposed between the first surface 21 of the second semiconductor chip C2 and the second surface 32 of the third semiconductor chip C3. The second underfill film 92 may have the same properties as the first underfill film 91, for example, the first underfill film 91 and the second underfill film 92 may be formed of the same material.

The molding layer 90c may cover sides of the first to third semiconductor chips C1, C2, and C3. In addition, the molding layer 90c may cover the sides of the first and second underfill films 91 and 92 between the first to third semiconductor chips C1, C2, and C3. If the first and second underfill films 91 and 92 are formed of the same material as the molding layer 90c, the first and second underfill films 91 and 92 may not be distinguished from the molding layer 90c. The molding layer 90c may correspond to the molding layer 90 shown in FIG. 1.

In the semiconductor stack package 100c, the formation of a void may be prevented among the first to third semiconductor chips C1, C2, and C3 by using the first and second underfill films 91 and 92.

FIG. 4 is a cross-sectional view of a semiconductor stack package 100d according to yet another embodiment of the inventive concept.

Referring to FIG. 4, the semiconductor stack package 100d is substantially the same as the semiconductor stack package 100b shown in the embodiment of FIG. 2, except that the areas of the second and third semiconductor chips C2d and C3d are less than that of the first semiconductor chip C1. In addition, components shown in FIG. 4 which are not described may correspond to those shown in FIG. 1, and thus the descriptions thereof will not be repeated.

The semiconductor stack package 100d includes first to third semiconductor chips C1, C2d, and C3d. The first semiconductor chip C1 is described above with reference to FIG. 1, and thus the descriptions thereof will not be repeated. The second and third semiconductor chips C2d and C3d may correspond to the second and third semiconductor chips C2 and C3 shown in FIGS. 1 and 2.

As shown in FIG. 4, the areas of the second and third semiconductor chips C2d and C3d are less than that of the first semiconductor chip C1 formed on the second and third semiconductor chips C2d and C3d. Generally, semiconductor chips are stacked from the bottom of a semiconductor stack package, and thus the area of a lower semiconductor chip is greater than an upper semiconductor chip. If the area of the upper semiconductor chip is greater than that of the lower semiconductor chip, a semiconductor wafer including the lower semiconductor chip may not be able to be diced, and it may be difficult to perform a molding process. However, the semiconductor stack package 100d according to the current embodiment is manufactured in the opposite direction of that of the general semiconductor stack package, i.e., in the reverse direction, and thus the area of the lower semiconductor chips C2d and C3d may be less than that of the upper semiconductor chip C1. This will be described later.

The area of the second semiconductor chip C2d is the same as that of the third semiconductor chip C3d in FIG. 4, but the inventive concept is not limited thereto. The second semiconductor chip C2d may have the same area as the first semiconductor chip C1. In addition, the area of the third semiconductor chip C3d may be less than that of the second semiconductor chip C2d. In addition, the third semiconductor chip C3d may have the same area as the first semiconductor chip C1.

The molding layer 90d may cover not only the first semiconductor chip C1 but also sides of the second and third semiconductor chips C2d and C3d. The molding layer 90d may correspond to the molding layer 90b shown in FIG. 2.

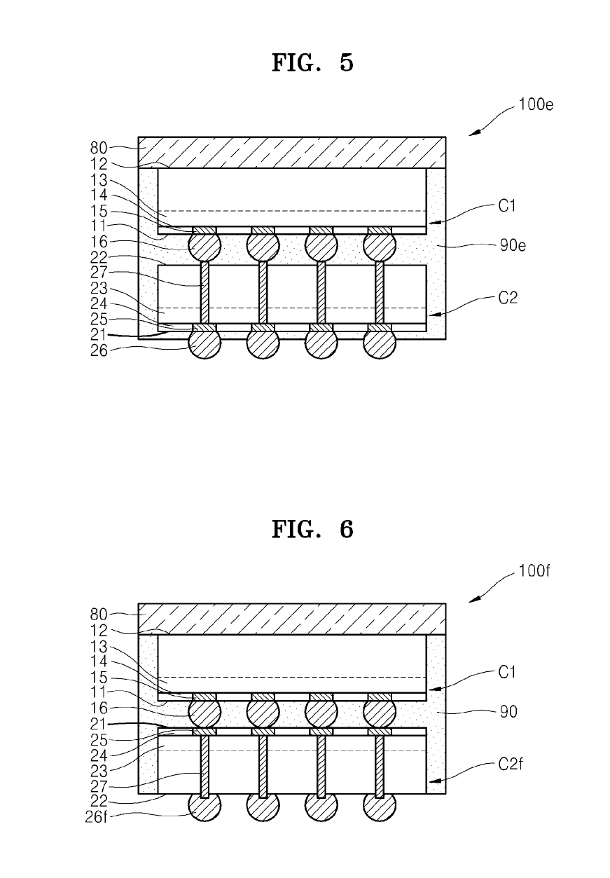

FIG. 5 is a cross-sectional view of a semiconductor stack package 100e according to still another embodiment of the inventive concept.

Referring to FIG. 5, the semiconductor stack package 100e is substantially the same as the semiconductor stack package 100a of FIG. 1, except that a molding layer 90e covers the first surface 21 of the second semiconductor chip C2. In addition, components shown in FIG. 5 which are not described may correspond to those shown in FIG. 1, and thus the descriptions thereof will not be repeated.

As shown in FIG. 5, the molding layer 90e may cover the first surface 21 to expose the second connection bump 26 of the second semiconductor chip C2. The molding layer 90e may correspond to the molding layer 90 shown in FIG. 1. The semiconductor stack package 100e according to the current embodiment is manufactured in the opposite direction of that shown in FIG. 4, i.e., in the reverse direction of FIG. 4, and thus the first surface 21 of the second semiconductor chip C2 may be covered with a liquid molding material. This will be described later.

The semiconductor stack package 100e, except for the second connection bumps 26 of the second semiconductor chip C2, is completely covered with the molding layer 90e and the chip protection film 80, so that the semiconductor stack package 100e may be protected from an external impact or moisture.

FIG. 6 is a cross-sectional view of a semiconductor stack package 100f according to still another embodiment of the inventive concept.

Referring to FIG. 6, the semiconductor stack package 100f is substantially the same as the semiconductor stack package 100a of FIG. 1, except that a first surface 21 of a second semiconductor chip C2f is disposed to face the first semiconductor chip C1. In addition, components shown in FIG. 6 which are not described may correspond to those shown in FIG. 1, and thus the descriptions thereof will not be repeated.

The semiconductor stack package 100f includes first and second semiconductor chips C1 and C2f. In the second semiconductor chip C2f, which is distinguished from the second semiconductor chip C2 of FIG. 1, the first surface 21, i.e., the active surface 21, faces the first semiconductor chip C1.

In other words, the second semiconductor chip C2 of the semiconductor stack package 100a shown in FIG. 1 has a “face down” form in which the first surface 21 faces down. However, in the semiconductor stack package 100f shown in FIG. 6, the second semiconductor chip C2f may have a “face up” form in which the active layer 21 faces up.

Accordingly, unlike the semiconductor stack package 100a shown in FIG. 1, the semiconductor stack package 100f shown in FIG. 6 has a “face to face” form in which the active surfaces of the first semiconductor chip C1 and second semiconductor chip C2f face toward each other.

The second semiconductor chip C2f may include a second connection bump 26f attached to the second surface 22. The second connection bump 26f may be directly electrically connected to the second through electrode 27. In addition, the first connection bump 16 attached to the first pad 15 of the first semiconductor chip C1 may be directly connected to the second pad 25.

The semiconductor stack package 100f may be a semiconductor stack package that is applicable when a signal transmission rate between the first semiconductor chip C1 and the second semiconductor chip C2f is significant.

Characteristics of the semiconductor stack packages described in embodiments with reference to FIGS. 1 to 6 may be independently applied to the semiconductor stack package or may be combined and then applied to the semiconductor stack package. For example, the characteristics of the semiconductor stack package 100f shown in FIG. 6 may be combined with the semiconductor stack package 100e. That is, the second surface 22 of the second semiconductor chip C2f which is not covered with a protection layer and exposed may be covered with a molding layer that exposes a second connection bump 26f.

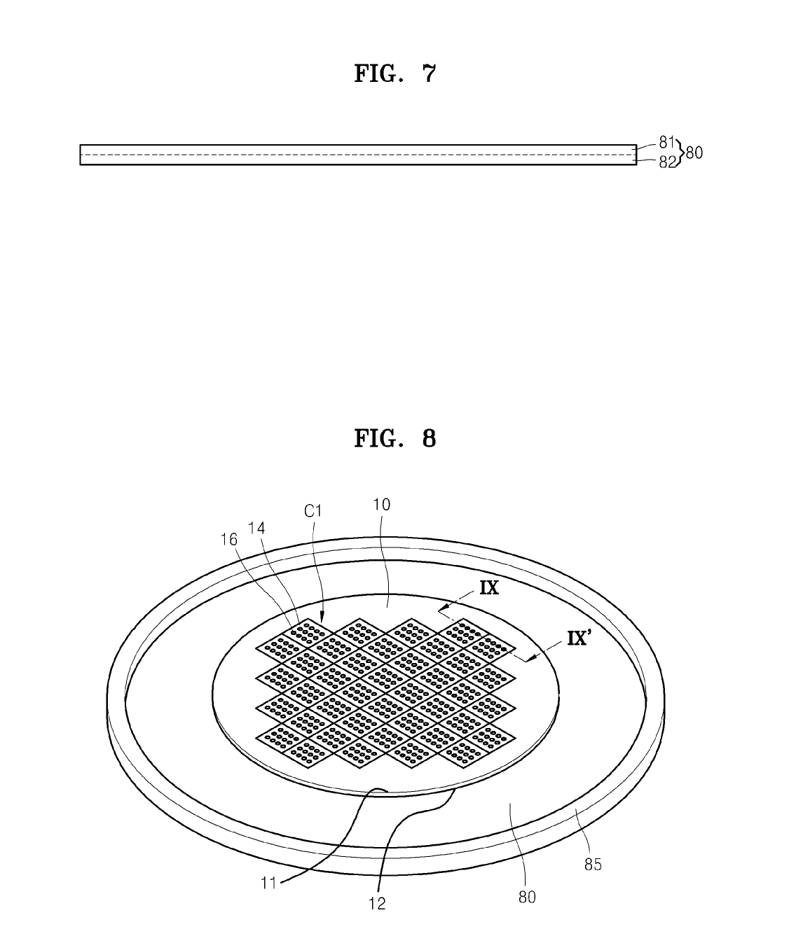

FIGS. 7 to 14 are diagrams describing a method of fabricating a semiconductor stack package according to the embodiment of FIG. 1, according to a fabricating order.

FIG. 7 is a cross-sectional view describing preparing a chip protection film according to the embodiment of FIG. 1.

FIG. 7 shows a chip protection film 80. The chip protection film 80 may include an adhesive layer 81 and a protection layer 82. The adhesive layer 81 and the protection layer 82 are formed of a material that protects the surface of the semiconductor chip.

The adhesive layer 81 and the protection layer 82 may be formed of materials with similar properties, for example, the same material having different phases. In this regard, the adhesive layer 81 may have a B-stage phase, and the protection layer 82 may have a C-stage phase. Here, the B-stage phase indicates a phase that is not cured even though a solvent is removed from an A-stage phase, which is an initial stage of a thermosetting resin, i.e., a phase that is not melted, swells in a solvent, but is not dissolved in the solvent. Accordingly, the A-stage phase generally turns to the B-stage phase by heat-treatment or UV rays. In addition, the C-stage phase is a totally cured phase. Thus, the adhesive layer 81 in the B-stage phase has adhesive property, but the protection layer 82 in the C-stage phase is completely cured so as not to have an adhesive property.

The adhesive layer 81 and/or the protection layer 82 may include an epoxy, a silicon, a polyimide, or an acrylic material. In addition, the adhesive layer 81 and/or the protection layer 82 may include a phenol type, an acid anhydride type, or an amine type curing agent. The adhesive layer 81 and/or the protection layer 82 may include a heat sensitive material, a thermoplastic material, or an UV curable material having an acrylic polymer.

The chip protection film 80 may have a stack structure of the adhesive layer 81 and the protection layer 82 as described above, but the inventive concept is not limited thereto. The chip protection film 80 may have any other structure and may be formed of another material. In addition, the chip protection film 80 is schematically shown as a single layer without separately illustrating the adhesive layer 81 and the protection layer 82 in FIG. 7.

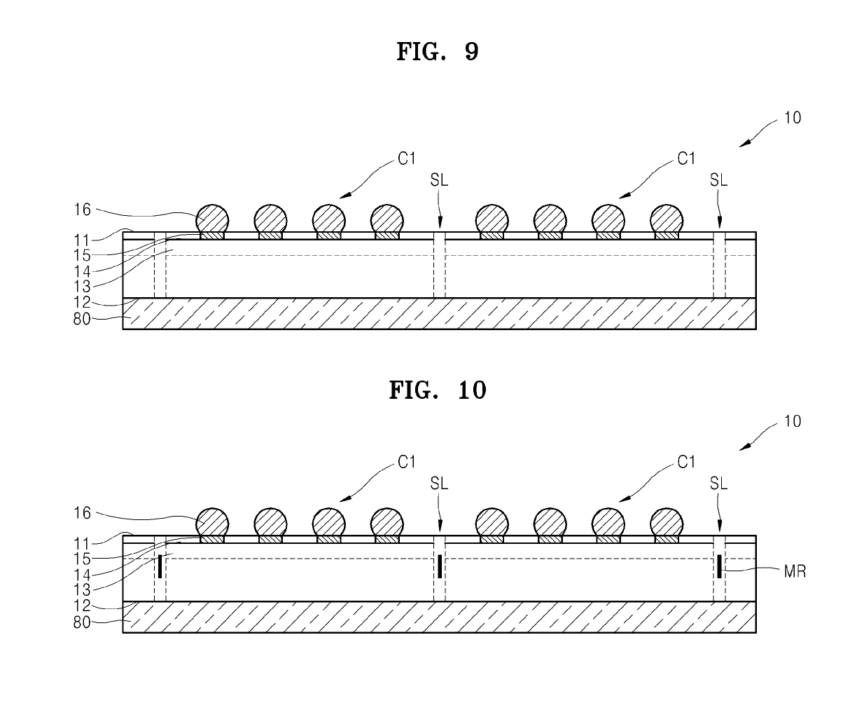

FIGS. 8 and 9 are respectively a schematic perspective view and a cross-sectional view describing adhering the first semiconductor substrate to the chip protection film according to the embodiment of FIG. 1.

Referring to FIG. 8, a first semiconductor substrate 10 and a support 85 may be attached to a chip protection film 80, for example, an adhesive layer 81 of the chip protection film 80 (FIG. 7). A second surface 12 of the first semiconductor substrate 10 is attached onto the chip protection film 80 to expose an active surface 11 of the first semiconductor substrate 10. The support 85 may have a circular shape having an inner diameter that is greater than the diameter of the semiconductor substrate 10. If a circular support 85 is used, the semiconductor substrate 10 is disposed in a circular support 85.

The first semiconductor substrate 10 may include a plurality of first semiconductor chips C1. The first surface 11 of the first semiconductor chip C1 may be exposed, and the protection layer 14 and a plurality of first connection bumps 16 for electrical connection with an external device may be formed on the first surface 11.

FIG. 9 is a cross-sectional view taken along line IX-IX′ of FIG. 8.

Referring to FIG. 9, the first semiconductor substrate 10 may be attached to the chip protection film 80 to expose the first surface 11. The first semiconductor substrate 10 may have a thickness that is less than that of a semiconductor wafer that undergoes a semiconductor processing. In other words, the first semiconductor substrate 10 may be a portion of the semiconductor wafer which remains after a chemical mechanical polishing (CMP) or an etching process.

The first semiconductor substrate 10 may have a chip region and a scribe line SL between the chip regions. The chip region is a region in which individual semiconductor devices are formed and will be the first semiconductor chip C1 after dicing. The scribe line SL is used to separate the individual semiconductor chips. Hereinafter, the term “scribe line” indicates a region found between individual chip regions on the semiconductor wafer in which the individual semiconductor device is not formed, a test pattern or a test semiconductor device to test if a wafer level is formed, or a dummy pattern to determine whether the stability of the process is formed.

The individual semiconductor device may be formed on the first surface 11 of the first semiconductor substrate 10. The first active region 13 in which the individual semiconductor device is formed may be formed on the first surface 11.

After the first active region 13 including the individual semiconductor device is formed on the first surface 11 of the first semiconductor substrate 10, the first protective layer 14 protecting the first active region 13 may be formed. The first protection layer 14 may be a single material layer or a stack of a plurality of material layers. The first protection layer 14 may be formed of an insulating material. The first protection layer 14 may include a nitride or an oxide.

The first semiconductor substrate 10 may include a first pad 15 that is exposed by the first protection layer 14. The first pad 15 may be electrically connected to the individual semiconductor device in the first active region 13.

A redistribution (not shown) may be formed between the first pad 15 and the first active region 13. The position of the first pad 15 may be changed by the redistribution. If there is the redistribution, the first protection layer 14 may have a multi-layered structure including a layer protecting the first active region 13 and an insulating layer for the redistribution.

The first connection bumps 16 may be formed on the first semiconductor substrate 10. The first connection bumps 16 may respectively be attached onto the first pad 15 to be in contact with the first pad 15.

The first connection bumps 16 may include one selected from the group consisting of a conductive bump, a conductive spacer, a solder ball, a pin grid array (PGA) and any combination thereof. The first active region 13 may be electrically connected to an external device such as another semiconductor chip via the first connection bump 16.

FIG. 10 is a cross-sectional view describing forming a modified region of the scribe line SL of the first semiconductor substrate according to the embodiment of FIG. 1.

Referring to FIG. 10, a modified region MR may be formed in the scribe line SL to separate the first semiconductor chip C1 of the first semiconductor substrate 10. For this, a laser beam may be irradiated to the scribe line SL of the first semiconductor substrate 10. The laser beam may be focused on the inside of the first semiconductor substrate 10, and thus the material of the first semiconductor substrate 10 is melted. Accordingly, a modified region MR may be formed in the scribe line SL. The modified region MR may be a starting point of the separation of the semiconductor chip.

Even though not shown in FIG. 10, the modified region MR may be formed on the first surface of the first semiconductor substrate 10 along the scribe line SL. For this, a laser saw or a blade saw may be used.

Alternatively, the first semiconductor substrate 10 may be cut into the first semiconductor chips C1 along the scribe line SL using the blade saw.

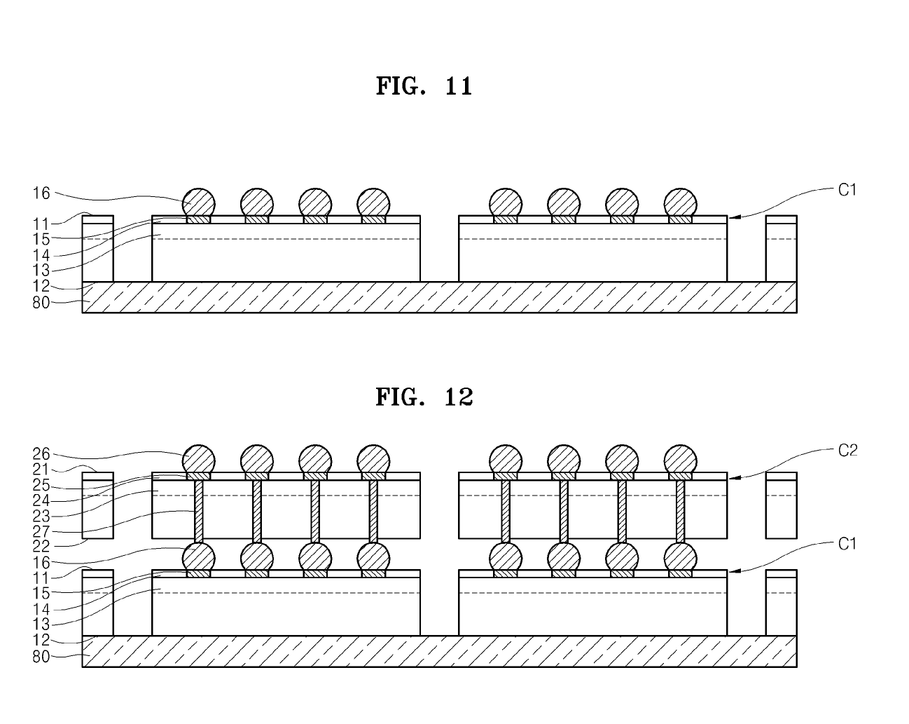

FIG. 11 is a cross-sectional view describing expanding the chip protection film to space the first semiconductor chips according to the embodiment of FIG. 1.

Referring to FIG. 11, the chip protection film 80 is expanded to separate the first semiconductor chips C1 from each other with respect to the modified region MR of FIG. 10. Since the first semiconductor substrate 10 mainly has a single crystalline structure, the first semiconductor chips C1 may break with respect to the modified region MR by a force to be separated from each other. In addition, if the chip protection film 80 is further expanded, the first semiconductor chips C1 may be spaced apart from each other as shown in FIG. 11. The first semiconductor chips C1 may be spaced apart from each other by about 70 μm or more. For this, the chip protection film 80 may be formed of an elastic and adhesive material.

Referring to FIG. 8, a force may be applied to a surface of the chip protection film 80 opposite to the first semiconductor substrate 10, i.e., upward in FIG. 11, while the circular support 85 is fixed around the first semiconductor substrate 10 in order to expand the chip protection film 80. For example, the chip protection film 80 may be expanded by moving the chip protection film 80 upward or downward using a support plate (not shown) having a circular cross-section with a diameter greater than the diameter of the first semiconductor substrate 10 and less than the inner diameter of the circular support 85.

Alternatively, the support 85 that is attached around the first semiconductor substrate 10 moves or expands to the outside of the first semiconductor substrate 10, so that the chip protection film 80 may be expanded. In this regard, the support 85 may apply a uniform force to the outside of the first semiconductor substrate 10.

The chip protection film 80 may be expanded by using the two methods described above, but the inventive concept is not limited thereto. Any method of applying a uniform force to the circumference of the first semiconductor substrate 10 toward the outside of the first semiconductor substrate 10 in order to expand the chip protection film 80 may also be used.

The support 85 may maintain the expanded state of the chip protection film 80. The phase of the expanded chip protection film 80 may be changed into a completely cured C-stage phase by heating or irradiating UV rays to the expanded chip protection film 80. Alternatively, the chip protection film 80 may be completely cured in a complete curing process of a molding material which will be described later to turn into the completely cured C-stage phase.

FIG. 12 is a cross-sectional view describing attaching the second semiconductor chips to the first semiconductor chips according to the embodiment of FIG. 1.

Referring to FIG. 12, the second semiconductor chips C2 are attached to the spaced apart first semiconductor chips C1. Each of the second semiconductor chips C2 may respectively be attached to correspond to each of the first semiconductor chips C1.

The second semiconductor chips C2 may include the second active region 23 in which the individual semiconductor devices are formed. A second protection layer 24 to protect the second active region 23 and a second pad 25 exposed by the second protection layer 24 may be formed on the first surface 21 of the second semiconductor chip C2. In addition, the second connection bumps 26 which are electrically connected to the second pad 25 may be attached to the second pad 25. The second semiconductor chip C2 may include the second through electrode 27 passing through the second semiconductor chip C2.

Characteristics of the second active region 23, the second protection layer 24, and the second pad 25 of the second semiconductor chip C2 which are not described herein may be the same as those of the first active region 13, the first protection layer 14, and the first pad 15 of the first semiconductor chip C1.

The second surface 22 of the second semiconductor chip C2 may be attached to face the first semiconductor chip C1. The second through electrode 27 exposed to the second surface 22 of the second semiconductor chip C2 may contact the first connection bump 16 of the first semiconductor chip C1 to be electrically connected thereto. In addition, the second through electrode 27 may be electrically connected to the second active region 23 or the second connection bump 26. Accordingly, the second connection bump 26 may be electrically connected to the first active region 13 and/or the second active region 23 via the second through electrode 27.

The second semiconductor chip C2 may be disposed on the first semiconductor chip C1, and the second through electrode 27 may be bonded to the first connection bump 16 by a thermo-compression process. Alternatively, a plurality of the second semiconductor chips C2 are disposed on a plurality of the first semiconductor chips C1, and the second through electrodes 27 may be simultaneously bonded to the first connection bumps 16 by a reflow process.

FIG. 13 is a cross-sectional view describing forming a molding layer according to the embodiment of FIG. 1.

Referring to FIG. 13, the molding layer 90 is formed between the first semiconductor chips C1, between the second semiconductor chips C2, and between the first semiconductor chip C1 and the second semiconductor chip C2. The molding layer 90 may expose the first surface 21 of the second semiconductor chip C2.

For this, a molding material in the A-stage phase (not shown) may be injected between the first semiconductor chips C1, between the second semiconductor chips C2, and between the first semiconductor chip C1 and the second semiconductor chip C2. The molding material may be injected by dispensing, screen printing or spin coating. By dispensing, the molding material may be injected between the first semiconductor chips C1 and between the first semiconductor chip C1 and the second semiconductor chip C2 along gaps between the second semiconductor chips C2 by capillary phenomenon.

The molding material may include an epoxy, a silicon, a polyimide, or an acrylic material or ceramic, and may be formed of a material including a phenol type, an acid anhydride type, or an amine type curing agent and/or UV curable material.

The molding material may become the molding layer 90 in the completely cured C-stage phase by heat-treatment or UV irradiation. If the chip protection film 80 or the molding layer 90 is partially in the B-stage phase that is not completely cured, they may be simultaneously cured to have the C-stage phase. Thus, the chip protection film 80 and the molding layer 90 have the completely cured C-stage phase to protect the first semiconductor chip C1 and the second semiconductor chip C2.

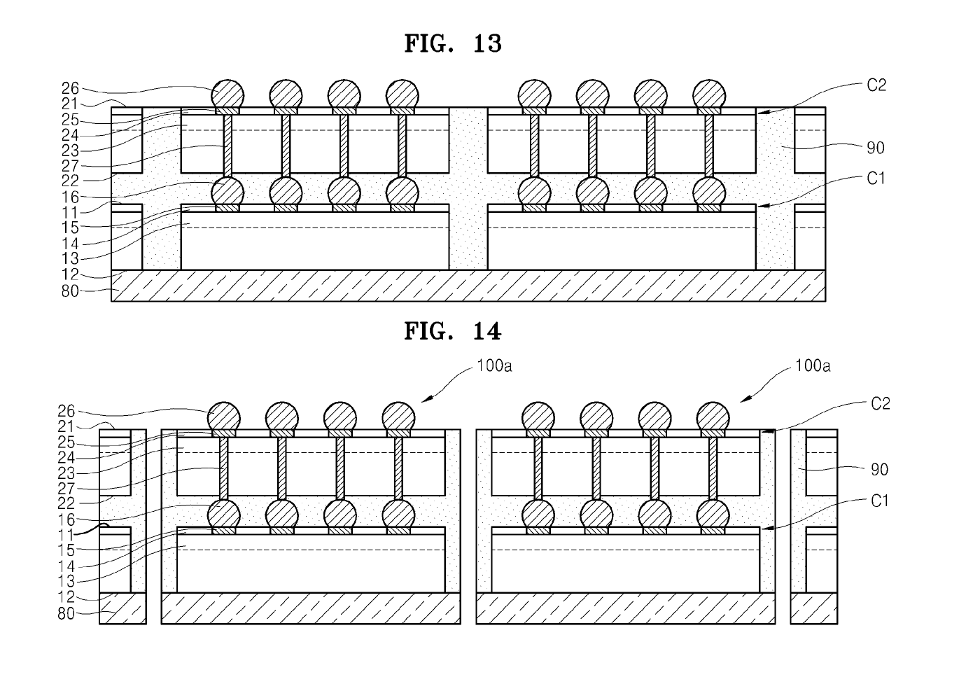

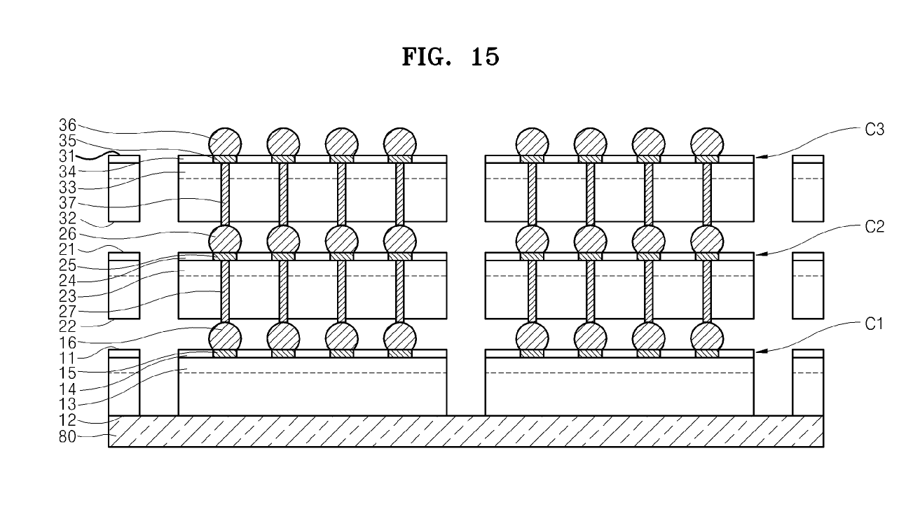

FIG. 14 is a cross-sectional view describing sawing the molding layer and the chip protection film according to the embodiment of FIG. 1.

Referring to FIG. 14, the molding layer 90 and the chip protection film 80 are sawed between the second semiconductor chips C2 to form the semiconductor stack package 100a. The molding layer 90 and the chip protection film 80 may be sawed by using a laser saw and blade saw. This process may be referred to as a singulation process.

The semiconductor stack package 100a may be protected against an external impact by the molding layer 90 and the chip protection film 80. In other words, sides of the semiconductor stack package 100a may be protected by the molding layer 90, and the second surface 12 of the first semiconductor chip C1 may be protected by the chip protection film 80.

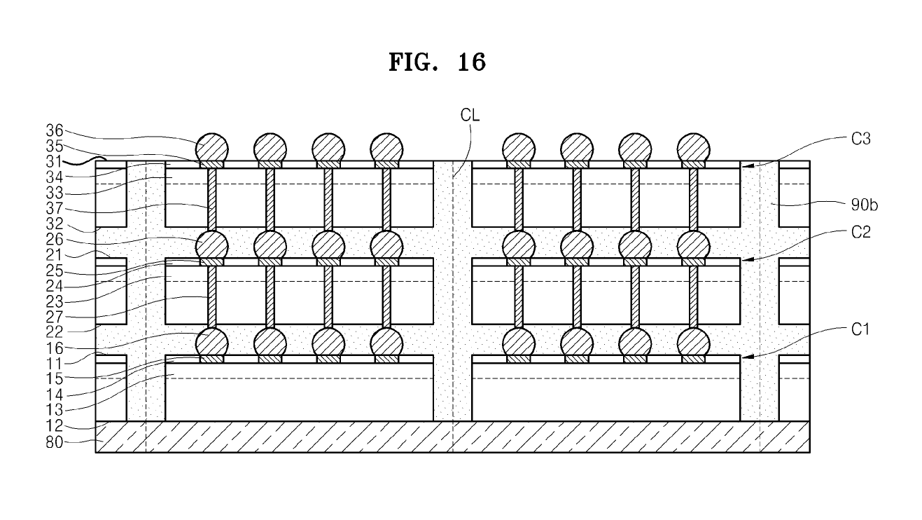

FIGS. 15 and 16 are diagrams describing a method of fabricating a semiconductor stack package according to the embodiment of FIG. 2.

FIG. 15 is a cross-sectional view describing attaching the second and third semiconductor chips onto the first semiconductor chip according to the embodiment of FIG. 2. FIG. 15 illustrates a subsequent process to the method of fabricating the semiconductor stack package according to the embodiment shown in FIGS. 7 to 11.

Referring to FIG. 15, second and third semiconductor chips C2 and C3 are attached onto the spaced first semiconductor chips C1 shown in FIG. 11. Each of the second and third semiconductor chips C2 and C3 may respectively be attached to each of the first semiconductor chips C1 to correspond thereto.

The second semiconductor chip C2 is described above with reference to FIG. 12, and thus the descriptions thereof will not be repeated.

The third semiconductor chip C3 may include the third active region 33 in which each of the individual semiconductor devices is formed. In addition, the third protection layer 34 to protect the third active region 33 and the third pad 35 exposed by the third protection layer 34 may be formed on the first surface 31 of the third semiconductor chip C3. In addition, the third connection bumps 36 which are electrically connected to the third pad 35 may be attached to the third pad 35. The third semiconductor chip C3 may include the third through electrode 37 passing through the third semiconductor chip C3.

The third semiconductor chip C3 may be attached onto the second semiconductor chip C2 so that the second surface 32 of the third semiconductor chip C3 faces the second semiconductor chip C2. The third through electrode 37 exposed to the second surface 32 of the third semiconductor chip C3 may contact the second connection bump 26 of the second semiconductor chip C2 to be electrically connected thereto. In addition, the third through electrode 37 may be electrically connected to the third active region 33 or the third connection bump 36. Accordingly, the third connection bump 36 may be electrically connected to the first active region 13, the second active region 23 and/or the third active region 33 via the third through electrode 37 and the second through electrode 27.

After attaching the second semiconductor chip C2 onto the first semiconductor chip C1 as shown in FIG. 12, the third semiconductor chip C3 may be attached onto the second semiconductor chip C2. Alternatively, after attaching the third semiconductor chip C3 onto the second semiconductor chip C2, the second and third semiconductor chips C2 and C3 may be attached onto the first semiconductor chips C1.

The bonding between the second through electrode 27 and the first connection bump 16, and the bonding between the third through electrode 37 and the second connection bump 26 may be separately performed by a thermo-compression or may be simultaneously performed by a reflow process.

FIG. 16 is a cross-sectional view describing forming a molding layer according to the embodiment of FIG. 2.

Referring to FIG. 16, the molding layer 90b is formed between the first semiconductor chips C1, between the second semiconductor chips C2, between the third semiconductor chips C3, between the first semiconductor chip C1 and the second semiconductor chip C2, and between the second semiconductor chip C2 and the third semiconductor chip C3.

For this, a molding material in the A-stage phase (not shown) may be injected among the first to third semiconductor chips C1, C2, and C3 and completely cured.

Then, the molding layer 90b and the chip protection film 80 are sawed along a cutting line CL to separate the semiconductor stack packages 100b shown in FIG. 2.

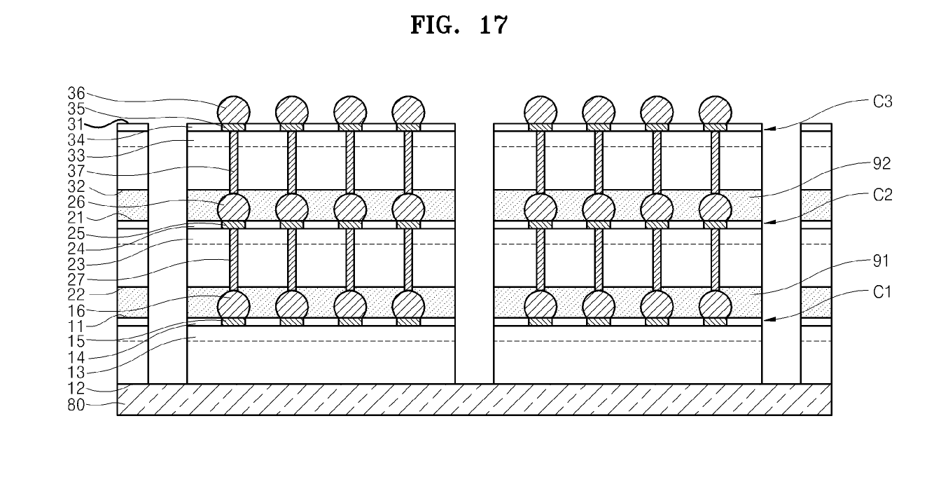

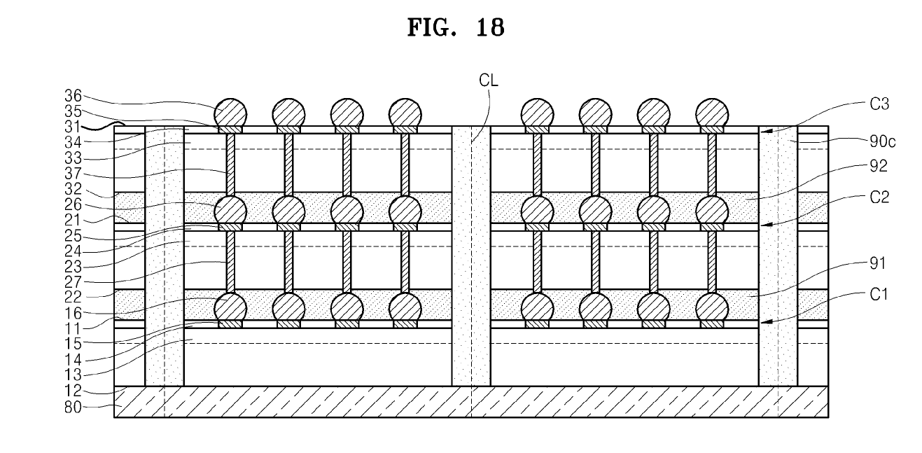

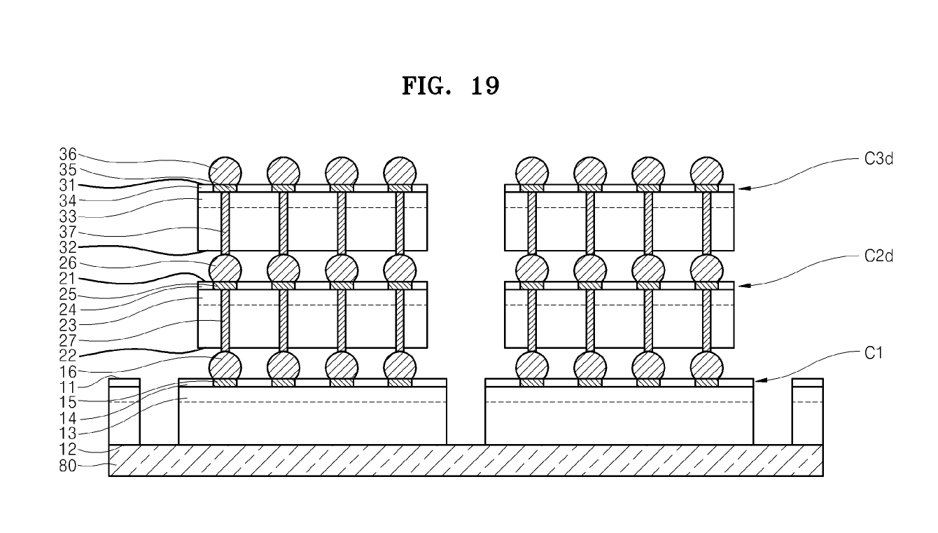

FIGS. 17 and 18 are diagrams describing a method of fabricating a semiconductor stack package according to still another embodiment of the inventive concept.

FIG. 17 is a cross-sectional view describing attaching the second and third semiconductor chips onto the first semiconductor chip using an underfill film according to the present embodiment. FIG. 17 illustrates a subsequent process to the method of fabricating the semiconductor stack package according to the embodiment shown in FIGS. 7 to 11.

Referring to FIG. 17, the second and third semiconductor chips C2 and C3 are sequentially attached onto the spaced first semiconductor chips C1 shown in FIG. 11 using first and second underfill films 91 and 92.

The first underfill film 91 may be interposed between the first surface 11 of the first semiconductor chip C1 and the second surface 22 of the second semiconductor chip C2. The first underfill film 91 may be attached to the second surface 22 of the second semiconductor chip C2, and then used to attach the second semiconductor chip C2 onto the first semiconductor chip C1. In this regard, the second semiconductor chip C2 may be thermally pressed toward the first semiconductor chip C1 so that the first connection bump 16 is inserted into the first underfill film 91.

Alternatively, the first connection bump 16 may be bonded to the second through electrode 27 by disposing an underfill material on the first surface 11 of the first semiconductor chip C1 to cover the first connection bump 16 and thermally pressing the second semiconductor chip C2 toward the first semiconductor chip C1.

The second underfill film 92 may be interposed between the first surface 21 of the second semiconductor chip C2 and the second surface 32 of the third semiconductor chip C3. The second underfill film 92 and the first underfill film 91 may be used in a substantially similar way.

FIG. 18 is a cross-sectional view describing forming a molding layer according to the present embodiment.

Referring to FIG. 18, the molding layer 90c is formed between each of the first semiconductor chips C1, between each of the second semiconductor chips C2, and between each of the third semiconductor chips C3.

For this, a molding material in the A-stage phase (not shown) may be injected between the first semiconductor chips C1, between the second semiconductor chips C2, and between the third semiconductor chip C3 and completely cured. As shown in FIG. 18, the molding layer 90c is not bent or branched, but instead has a linear shape. Accordingly, the formation of a void in the molding layer 90c may be reduced compared to the formation of a void in the molding layer 90b shown in FIG. 16.

Then, the molding layer 90c and the chip protection film 80 are sawed along a cutting line CL to separate the semiconductor stack packages 100c shown in FIG. 3.

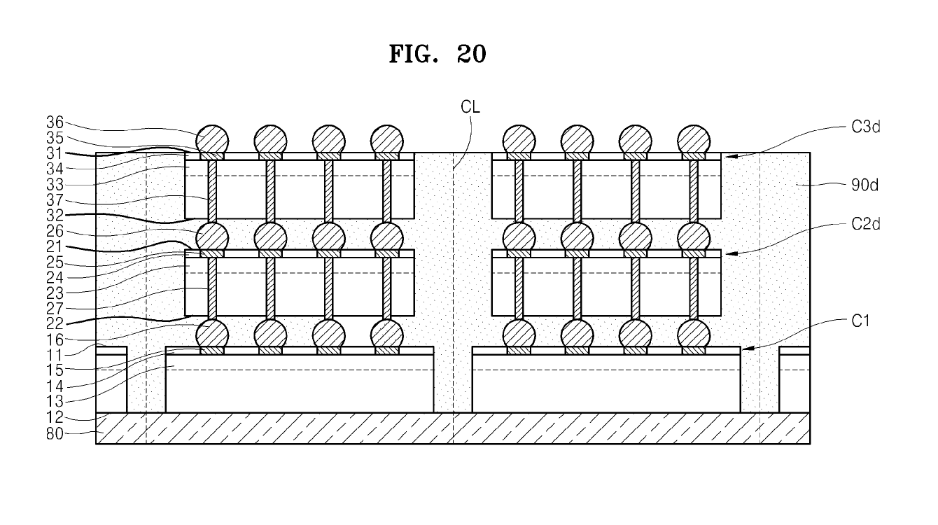

FIGS. 19 and 20 are diagrams for describing a method of fabricating a semiconductor stack package according to the fourth embodiment of the inventive concept according to a fabricating order.

FIG. 19 is a cross-sectional view for describing attaching second and third semiconductor chips onto the first semiconductor chip according to the fourth embodiment, wherein the areas of the second and third semiconductor chips are less than that of the first semiconductor chip. FIG. 19 illustrates a subsequent process to the method of fabricating the semiconductor stack package according to the first embodiment shown in FIGS. 7 to 11.

Referring to FIG. 19, second and third semiconductor chips C2d and C3d which have a smaller area than that of the first semiconductor chips C1 are attached onto the spaced first semiconductor chips C1 shown in FIG. 11.

Although not shown in FIG. 19, the underfill films 91 and 92 described with reference to FIG. 17 may be used to attach the second and third semiconductor chips C2d and C3d onto the first semiconductor chips C1.

FIG. 20 is a cross-sectional view for describing forming a molding layer according to yet another embodiment.

Referring to FIG. 20, the molding layer 90d is formed between the first semiconductor chips C1, between the second semiconductor chips C2d, between the third semiconductor chips C3d, between the first semiconductor chip C1 and the second semiconductor chip C2d, and between the second semiconductor chip C2d and the third semiconductor chip C3d.

For this, a molding material in the A-stage phase (not shown) may be injected among the first to third semiconductor chips C1, C2d, and C3d and completely cured. As shown in FIG. 20, since the space between the second and third semiconductor chips C2d and C3d is greater than that between the first semiconductor chips C1, the molding material may be efficiently injected thereinto. In addition, an underfill process may be first performed between the first semiconductor chip C1 and the second semiconductor chip C2d and between the second semiconductor chip C2d and the third semiconductor chip C3d using the wide space between the second and third semiconductor chips C2d and C3d.

Then, the molding layer 90d and the chip protection film 80 are sawed along a cutting line CL to separate the semiconductor stack packages 100d shown in FIG. 4.

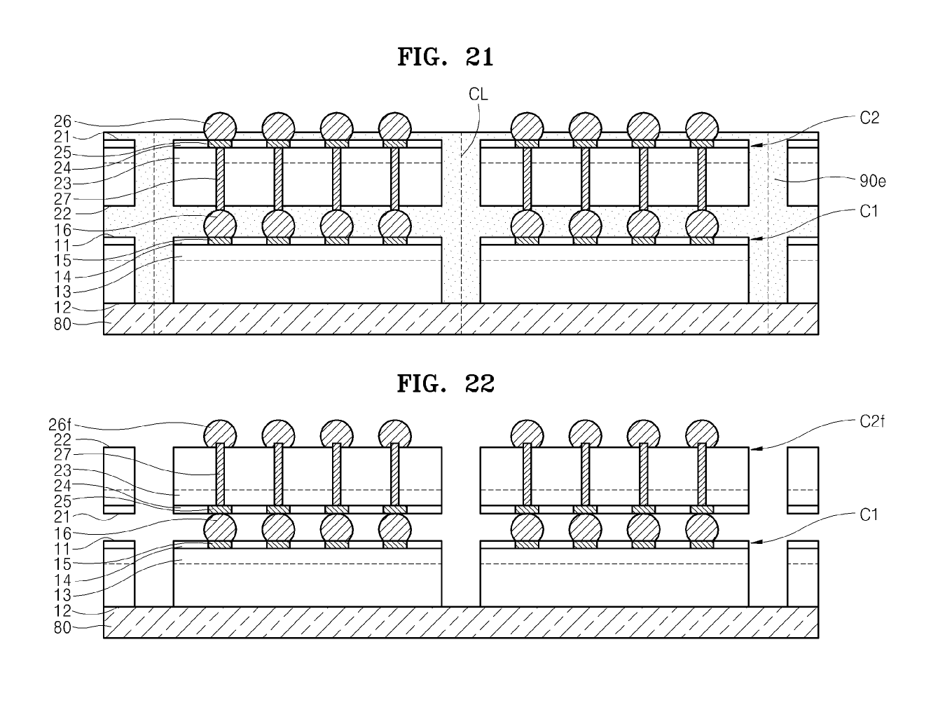

FIG. 21 is a diagram describing a method of fabricating a semiconductor stack package according to still another embodiment of the inventive concept.

FIG. 21 is a cross-sectional view describing forming a molding layer according to the present embodiment. FIG. 21 illustrates a subsequent process to the method of fabricating the semiconductor stack package according to the embodiment shown in FIGS. 7 to 12.

Referring to FIG. 21, the molding layer 90e is formed on a stack structure including the first semiconductor chips C1 and the second semiconductor chips C2 shown in FIG. 12. The molding layer 90e may cover the first surface 21 while exposing the second connection bump 26 of the second semiconductor chip C2.

For this, a molding material in the A-stage phase (not shown) may be filled between the first and second semiconductor chips C1 and C2d and excessively injected therein so as to cover the first surface 21 while exposing the second connection bump 26 of the second semiconductor chip C2. Then, the molding material may be completely cured. As shown in FIG. 21, since the first surface 21 of the second semiconductor chip C2 is disposed upward, the first surface 21 may be covered with a liquid molding material.

Then, the molding layer 90e and the chip protection film 80 are sawed along a cutting line CL to separate the semiconductor stack packages 100e shown in FIG. 5.

FIG. 22 is a diagram describing a method of fabricating a semiconductor stack package according to yet another embodiment of the inventive concept.

FIG. 22 is a cross-sectional view describing attaching the second semiconductor chips to the first semiconductor chips according to the present embodiment. FIG. 22 illustrates a subsequent process to the method of fabricating the semiconductor stack package according to the embodiment shown in FIGS. 7 to 11.

Referring to FIG. 22, second semiconductor chips C2f are attached onto the spaced first semiconductor chips C1 shown in FIG. 11. The second surface 21 of the second semiconductor chip C2f may be disposed to face the first semiconductor chip C1. The second semiconductor chip C2f may include a second connection bump 26f attached to the second surface 22. The second connection bump 26f may be directly electrically connected to the second through electrode 27. In addition, the first connection bump 16 attached to the first pad 15 of the first semiconductor chip C1 may be directly connected to the second pad 25.

Then, referring to FIG. 13, the molding layer 90 is formed between the first semiconductor chips C1, between the second semiconductor chips C2, and between the first semiconductor chip C1 and the second semiconductor chip C2. The molding layer 90 may expose the second surface 22 and the second connection bump 26f of the second semiconductor chip C2.

Then, the molding layer 90e and the chip protection film 80 are sawed between the second semiconductor chips C2 as shown in FIG. 14 to separate the semiconductor stack packages 100f shown in FIG. 6.

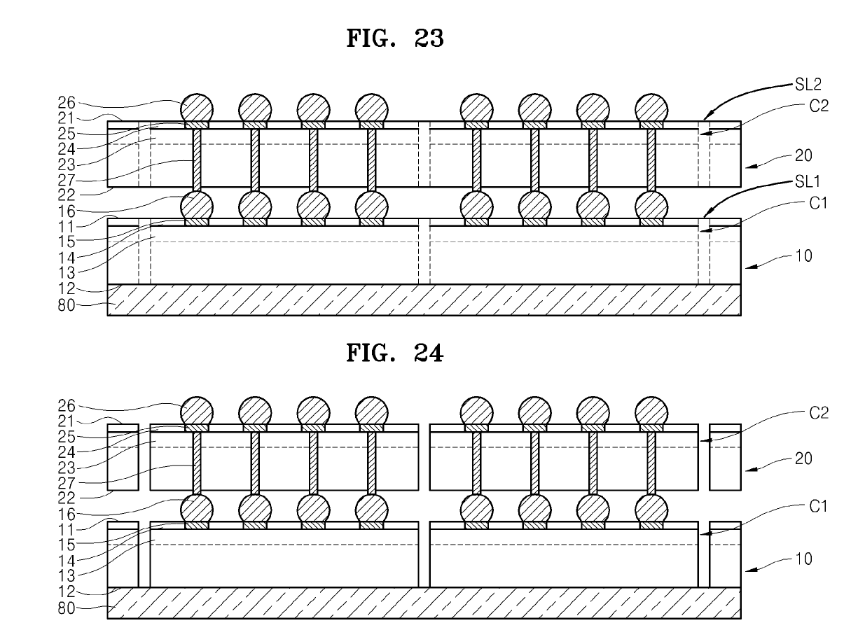

FIGS. 23 and 24 are diagrams describing a method of fabricating a semiconductor stack package according to a modified embodiment of the embodiment of FIG. 1 according to a fabricating order.

FIG. 23 is a cross-sectional view describing attaching a second semiconductor substrate onto a first semiconductor substrate according to the embodiment of FIG. 1. FIG. 23 illustrates a subsequent process to the method of fabricating the semiconductor stack package according to the embodiment shown in FIGS. 7 to 9.

Referring to FIG. 23, a second semiconductor substrate 20 is attached onto the first semiconductor substrate 10 that is attached to the chip protection film 80. The second semiconductor substrate 20 may be attached to the first semiconductor substrate 10 so as to correspond to the first semiconductor substrate 10. A first scribe line SL1 of the first semiconductor substrate 10 shown in FIG. 23 may correspond to the scribe line SL shown in FIG. 9.

The second semiconductor substrate 20 may include a plurality of second semiconductor chips C2. The first surface 21 of the second semiconductor chip C2 may be exposed, and the protection layer 24 and a plurality of second connection bumps 26 for electrical connection with an external device may be formed on the first surface 21.

The second semiconductor substrate 20 may have a chip region that will be the second semiconductor chip C2 and a second scribe line SL2 between the chip regions. The chip region is a region in which individual semiconductor devices are formed and which will be the first semiconductor chip C1 after dicing. The scribe line SL2 is used to separate the individual semiconductor chips.

The individual semiconductor devices may be formed on the first surface 21 of the second semiconductor substrate 20. The second active region 23 in which the individual semiconductor devices are formed may be formed on the first surface 21. A second protection layer 24 protecting the second active region 23 may be formed on the first surface 21 of the second semiconductor substrate 20. The second semiconductor substrate 20 may include the second pad 25 that is exposed by the second protection layer 24. The second connection bump 26 may be formed on the second pad 25 of the second semiconductor substrate 20. The second semiconductor chip C2 may include a the second through electrode 27 that is electrically connected to the second pad 25. The second through electrode 27 may be partially electrically connected to the second active region 23.

The alignment of the first semiconductor chips C1 of the first semiconductor substrate 10 substantially corresponds to that of the second semiconductor chips C2 of the second semiconductor substrate 20. That is, the chip region of the second semiconductor substrate 20 corresponds to that of the first semiconductor substrate 10. For example, as shown in FIG. 23, the first scribe line SL1 of the first semiconductor substrate 10 and the second scribe line SL2 of the second semiconductor substrate 20 may be aligned to be in the same vertical line. If the area of the first semiconductor chip C1 is greater than that of the second semiconductor chip C2, the area of the first semiconductor chip C1 includes the area of the second semiconductor chip C2 in a vertical line. In addition, the first semiconductor substrate 10 may be substantially identical to the second semiconductor substrate 20. Although the first semiconductor substrate 10 does not include a through electrode in FIG. 23, the first semiconductor substrate 10 may include a through electrode as the second through electrode 27 of the second semiconductor substrate 20.

Although not shown in FIG. 23, the second semiconductor substrate 20 may be attached onto the first semiconductor substrate 10 using an underfill film.

FIG. 24 is a cross-sectional view for describing sawing the first semiconductor substrate and the second semiconductor substrate according to the embodiment of FIG. 1.

Referring to FIG. 24, the second semiconductor substrate 20 and the first semiconductor substrate 10 are simultaneously sawed along the scribe line SL. Accordingly, the second semiconductor substrate 20 is separated from the second semiconductor chips C2, and the first semiconductor substrate 10 is separated from the first semiconductor chips C1. Thus, the second semiconductor chips C2 are attached to their corresponding first semiconductor chips C1.

Then, the first semiconductor chips C1 are spaced apart from each other by expanding the chip protection film 80 as shown in FIG. 11. As described above, since the second semiconductor chips C2 are attached to the first semiconductor chips C1, the second semiconductor chips C2 are also spaced apart from each other. Accordingly, the structure will be the same as that shown in FIG. 12. Then, the process described with reference to FIGS. 13 and 14 may be applied thereto.

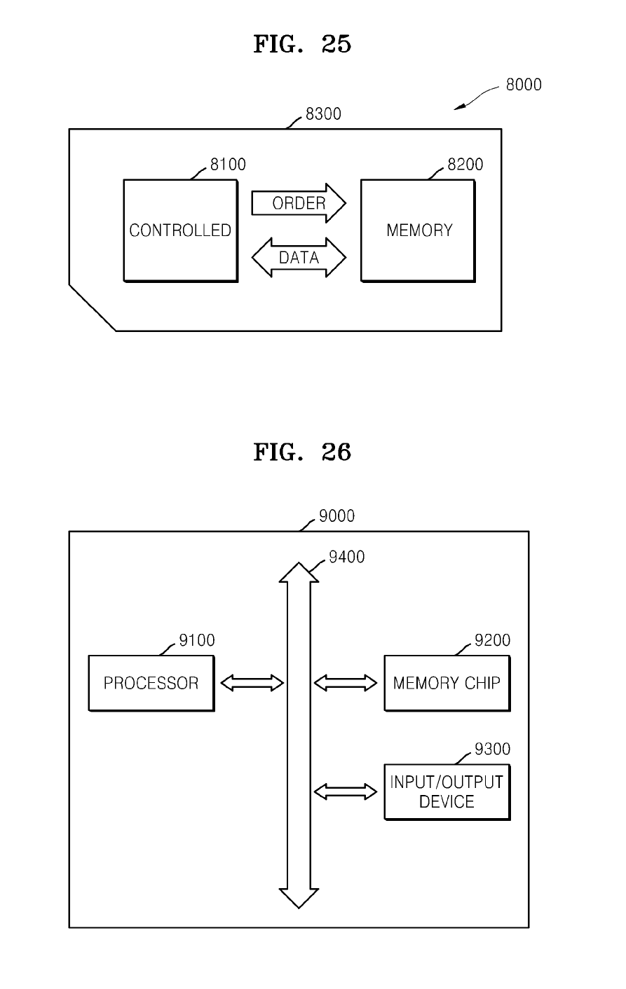

FIG. 25 is a schematic block diagram illustrating a memory card according to an embodiment of the inventive concept.

Referring to FIG. 25, a memory card 8000 may include a controller 8100 and a memory 8200 embedded in a housing 8300. The controller 8100 and the memory 8200 may exchange an electrical signal. For example, the memory 8200 and the controller 8100 may exchange data according to an order from the controller 8100. Accordingly, the memory card 8000 may store data in the memory 8200 or output data from the memory 8200.

For example, the memory 8200 may be one of the semiconductor stack packages 100a to 100f described above with reference to FIGS. 1 to 6. The memory card 8000 may be used as a data storage medium of a variety of portable devices. For example, the memory card 8000 may include a multi media card (MMC) or a secure digital card (SD).

The semiconductor stack package according to embodiments of the inventive concept may be stably protected by the molding layer and the chip protection film and the volume expansion of the semiconductor stack package may be minimized even when the memory chip or the controller is stacked thereon. Thus, a memory card 8000 that has high capacity, high performance, and high stability may be formed.

FIG. 26 is a schematic block diagram illustrating an electronic system according to an embodiment of the inventive concept.

Referring to FIG. 26, the electronic system 9000 may include a processor 9100, an input/output device 9300, and a memory chip 9200, which may exchange data using a bus 9400. The processor 9100 may execute a program and control the electronic system 9000. The input/output device 9300 may be used to input or output data from the electronic system 9000. The electronic system 9000 may be connected to an external device, e.g., a personal computer or a network via the input/output device 9300, in order to exchange data with the external device. The memory 9200 may store code and data for operating the processor 9100. For example, the memory 9200 may be one of the semiconductor stack packages 100a to 100f described above with reference to FIGS. 1 to 6.

The electronic system 9000 may be used in a variety of electronic control devices requiring the memory 9200, such as a mobile phone, a MP3 player, a navigation device, a solid state disk (SSD), and household appliances

The semiconductor stack package according to embodiments of the inventive concept may be stably protected by the molding layer and the chip protection film and the volume expansion of the semiconductor stack package may be minimized even when the memory chip or the controller is stacked thereon. Thus, an electronic system 9000 that has high capacity, high performance, and high stability may be formed.

While the inventive concept has been particularly shown and described with reference to exemplary embodiments thereof, it will be understood that various changes in form and details may be made therein without departing from the spirit and scope of the following claims.

What is claimed is:

1. A method of fabricating a semiconductor stack package, the method comprising:
attaching a first semiconductor substrate comprising a plurality of first semiconductor chips to a chip protection film;
expanding the chip protection film such that the plurality of the first semiconductor chips are spaced apart from each other;
attaching a plurality of second semiconductor chips, each of which comprises a through electrode, to the plurality of the first semiconductor chips such that each of the second semiconductor chips corresponds to each of the first semiconductor chips;
forming a molding layer between the plurality of the first semiconductor chips and between the plurality of the second semiconductor chips; and
sawing the molding layer and the chip protection film to separate the semiconductor stack package comprising the first semiconductor chips and the second semiconductor chips stacked on the first semiconductor chips.

2. The method of claim 1, wherein in the attaching the first semiconductor substrate to the chip protection film, the chip protection film comprises an adhesive layer having a B-stage phase and a protection layer having a C-stage phase, and
the first semiconductor substrate is attached to the adhesive layer of the chip protection film.

3. The method of claim 1, wherein the first semiconductor substrate has a first surface in which an active region is formed and a second surface that is opposite to the first surface, and
the second surface of the first semiconductor substrate is attached to the chip protection film.

4. The method of claim 3, wherein each of the plurality of first semiconductor chips comprises a first connection bump disposed on the first surface,
each of the plurality of second semiconductor chips comprises a second connection bump electrically connected to the through electrode, and
the plurality of the second semiconductor chips are attached to the plurality of the first semiconductor chips such that the through electrode is electrically connected to the first connection bump of the plurality of the first semiconductor chips.

5. The method of claim 1, further comprising:
sawing the first semiconductor substrate along a scribe line to separate the plurality of the first semiconductor chips from each other.

6. The method of claim 1, further comprising:
forming a modified region in the first semiconductor substrate along the scribe line using a laser beam,
wherein the plurality of the first semiconductor chips are separated from each other along the modified region in the expanding the chip protection film.

7. The method of claim 1, wherein forming the molding layer comprises:
injecting a molding material between the plurality of the first semiconductor chips and between the plurality of second semiconductor chips on the chip protection film; and
curing the molding material.

8. The method of claim 7, wherein the chip protection film is cured in the curing the molding material.

9. The method of claim 1, further comprising:
attaching a plurality of third semiconductor chips, each of which comprises a through electrode, to the plurality of the second semiconductor chips such that each of the third semiconductor chips corresponds to each of the second semiconductor chips,
wherein the molding layer is formed between the plurality of the third semiconductor chips in the forming the molding layer.

10. The method of claim 1, wherein the attaching the plurality of the second semiconductor chips to the first semiconductor substrate comprises:
attaching a plurality of third semiconductor chips, each of which comprises a through electrode, to the plurality of the second semiconductor chips such that each of the third semiconductor chips corresponds to each of the second semiconductor chips; and
attaching the plurality of the second semiconductor chips on which the plurality of the third semiconductor chips are stacked to the first semiconductor substrate.

11. The method of claim 1, wherein the attaching the plurality of the second semiconductor chips to the first semiconductor substrate comprises:
interposing an underfill film between the plurality of the second semiconductor chips and the plurality of the first semiconductor chips which correspond to each other, and attaching the plurality of the second semiconductor chips to the plurality of the first semiconductor chips by performing a thermo-compression.

12. The method of claim 1, wherein the area of the second semiconductor chip is less than that of the first semiconductor chip.

13. The method of claim 1, wherein the plurality of the second semiconductor chips have a first surface that faces the first semiconductor substrate and a second surface that is opposite to the first surface,
each of the plurality of the second semiconductor chips comprises a second connection bump formed on the second surface and electrically connected to the through electrode, and
the molding layer covers the second surface of the plurality of the second semiconductor chips to expose the second connection bump.

14. The method of claim 1, wherein the plurality of the second semiconductor chips are respectively attached to the plurality of the first semiconductor chips such that a surface on which the active region is formed to face the first semiconductor substrate.

15. The method of claim 7, wherein the molding material is injected by dispensing, screen printing or spin coating.

16. The method of claim 15, wherein the molding material includes at least one of an epoxy, a silicon, a polyimide, or an acrylic material or ceramic, and is formed of a material including a phenol type, an acid anhydride type, or an amine type curing agent and/or UV curable material.

17. A method of fabricating a semiconductor stack package, the method comprising:
preparing a first semiconductor substrate comprising a plurality of first semiconductor chips and a second semiconductor substrate comprising a plurality of second semiconductor chips;
attaching the first semiconductor substrate to a chip protection film;
attaching the second semiconductor substrate to the first semiconductor substrate such that the plurality of the second semiconductor chips respectively correspond to the plurality of the first semiconductor chips;
sawing the second semiconductor substrate and the first semiconductor substrate;
expanding the chip protection film such that the plurality of the first semiconductor chips are spaced apart from each other and the plurality of the second semiconductor chips are spaced apart from each other;
forming a molding layer between the plurality of the first semiconductor chips and between the plurality of the second semiconductor chips; and
sawing the molding layer and the chip protection film between the plurality of the second semiconductor chips.

18. A method of fabricating a semiconductor stack package, the method comprising:
preparing a first semiconductor substrate comprising a plurality of first semiconductor chips to a chip protective film;
expanding the chip protection film such that the plurality of the first semiconductor chips are spaced apart from each other;
sequentially attaching second and third semiconductor chips onto the spaced apart first semiconductor chips using first and second underfill films, respectively, such that the first underfill film is interposed between a first surface of the first semiconductor chip and a second surface of the second semiconductor chip and the second underfill film is interposed between a first surface of the second semiconductor chip and a second surface of the third semiconductor chip;
forming a molding layer between the first semiconductor chips, between the second semiconductor chips and the third semiconductor chips; and
cutting the molding layer and the chip protection film to separate into semiconductor stack packages.

19. The method of claim 18, wherein the first semiconductor chips are attached to the second semiconductor chips using through electrodes and the third semiconductor chips are connected to the second semiconductor chips using through electrodes such that first, second and third semiconductor chips correspond to each other.

20. The method of claim 19, wherein:
each of the plurality of first semiconductor chips comprises first connection bumps disposed on the first surface thereof,
each of the plurality of second semiconductor chips comprises second connection bumps electrically connected to the through electrodes thereof, and
the plurality of the second semiconductor chips are attached to the plurality of the first semiconductor chips such that the through electrodes are electrically connected to the first connection bumps of the plurality of the first semiconductor chips.
